(19) United States
(12) Patent Application Publication
(10) Pub. No.: US 2003/0167434 A1
(43) Pub. Date: Sep. 4, 2003

(54) Legacy-compatible forward error correction in telecommunications networks

(76) Inventor: Michael Andrew Fischer, San Antonio, TX (US)

Correspondence Address: DEMONT & BREYER, LLC, SUITE 250, 100 COMMONS WAY, HOLMDEL, NJ, 07733, US

(21) Appl. No.: 10/087,109

(22) Filed: Mar. 1, 2002

(51) Int. Cl. H03M 13/00

(52) U.S. Cl. 714/755

(57) ABSTRACT

A methodology for enabling terminals that perform forward error correction to interoperate with terminals that perform automatic-repeat-request is disclosed. This is advantageous because it does not require that all of the terminals be upgraded at once, which is an all-to-common fact of many migration paths. In accordance with the illustrative embodiment of the present invention, the legacy terminals communicate with a data frame that conforms to a legacy data frame format and the upgraded terminals communicate with a data frame that conforms to an upgraded data frame format, which is a legacy-compatible extension of the legacy data frame format. The legacy data frame format enables the detection, but not correction, of errors in a data frame and the upgraded data frame format enables the correction of errors in the data frame.

### FIELD OF THE INVENTION

The present invention relates to telecommunications in general, and, more particularly, to a technique for forward error correction that is legacy-compatible with automatic-repeat-request.

### BACKGROUND OF THE INVENTION

The problem of dealing with transmission errors in telecommunications networks has been studied for many years. In general, the solutions for dealing with transmission errors fall into two classes: (i) forward error control, and (ii) automatic-repeat-request.

In accordance with forward error control, data is encoded in accordance with an error-control coding scheme that increases the likelihood that the receiver can detect and correct any errors that might occur during transmission.

In accordance with automatic-repeat-request, data is encoded in accordance with an error-control coding scheme that that enables the receiver to detect, but not correct, errors that occur during transmission. In accordance with automatic-repeat-request, the receiver typically transmits back to the transmitter an acknowledgment that a data frame or packet has been received intact (i.e., a positive acknowledgement). If the transmitter does not receive the acknowledgment within a given time interval or if it receives an acknowledgement that the data frame has not been received intact (i.e., a negative acknowledgement), it retransmits the data frame again. This cycle continues until the transmitter receives a positive acknowledgement.

Both forward error control and automatic-repeat-request have advantages and disadvantages. One advantage of forward error control is that it avoids the temporal delay associated with automatic-repeat-request. One disadvantage of forward error control is that when the bit error rate is very low, forward error control can unnecessarily consume bandwidth in comparison with automatic-repeat-request. Another disadvantage of forward error control is that it consumes more in computation resources and in power (i.e., wattage) than automatic-repeat-request.

The advantage of automatic-repeat-request is that its error-control coding schemes typically require a lower data bit-to-parity bit ratio (i.e., less redundancy), and, therefore, consume less bandwidth. The disadvantage of automatic-repeat-request is that when the bit error rate is high, the retransmission of data frames unnecessarily consumes bandwidth in comparison with forward error control.

Today, there exist telecommunications networks where the terminals use automatic-repeat-request but where, because of the bit error rate, it would be more advantageous if the terminals used forward error control. Typically, however, it is prohibitively expensive and logistically impractical to simultaneously upgrade all of the terminals in a telecommunications network.

Therefore, the need exists for a technique for that enables the terminals in a telecommunications system to be upgraded to forward error control without the costs and logistical problems associated with migration strategies in the prior art.

### SUMMARY OF THE INVENTION

The present invention provides a technique for upgrading the terminals in a telecommunications system to forward error control without some of the costs and logistical problems associated with migration strategies in the prior art. For example, the illustrative embodiment enables terminals that perform forward error correction to interoperate with terminals that perform automatic-repeat-request, and vice-versa. This eliminates the need to upgrade all of the terminals simultaneously and allows upgraded terminals to be added to the network without affecting the operation of the legacy terminals.

In accordance with the illustrative embodiment of the present invention, the legacy terminals communicate with a data frame that conforms to a legacy data frame format. The legacy data frame format comprises: a header field, a payload field, and a framewide parity field. The header field is populated with information germane to the transmission of the data frame, and the payload field is populated with the information that constitutes the reason for which the data frame is created. The framewide parity field is populated with bits that enable the detection, but not correction, of one or more bit errors in the data frame.

When a legacy terminal receives a data frame that conforms to the legacy data frame format, it uses the bits in the framewide parity field to test the integrity of the data frame, which informs the legacy terminal whether or not it should acknowledge receipt of the data frame.

When an upgraded terminal receives a data frame that conforms to the legacy data frame format, it processes the data frame in exactly the same manner as the legacy terminal does.

In accordance with the illustrative embodiment of the present invention, the upgraded terminals communicate with a data frame that conforms to an upgraded data frame format, which is a legacy-compatible or “backwards-compatible” extension of the legacy data frame format. In other words, the upgraded data frame format also comprises the header field, payload field, and framewide parity field. In addition, however, the payload field further comprises three subfields: a payload data subfield, a first parity subfield, and a second parity subfield. The header field and the framewide parity field are populated in exactly the same manner as they are for the legacy data frame format. The payload data subfield is populated with the information that constitutes the reason for which the data frame is created (although it is appreciated that because of the presence of the first parity subfield and the second parity subfield in the payload field, the payload data subfield might not have the same capacity as the payload field in the legacy data frame format). The first parity subfield is populated with bits that enable the detection and correction of bit errors in the header field, and the second parity subfield is populated with bits that enable the detection and correction of bit errors in the payload data subfield.

When a legacy terminal receives a data frame that conforms to the upgraded data frame format, it processes it in the same manner as it does a data frame that conforms to the legacy data frame format. In fact, a legacy terminal cannot distinguish between a data frame that conforms to the upgraded data frame format and one that conforms to the legacy data frame format.

When an upgraded terminal receives a data frame that conforms to the upgraded data frame format, it recognizes that fact and uses the bits in the second and third parity subfields to detect and correct, if possible, any bit errors in the data frame's header field and payload data subfield.

Therefore, the upgraded data frame format in accordance with the illustrative embodiment enables terminals that perform forward error correction to interoperate with terminals that perform automatic-repeat-request, which obviates the need for upgrading all of the terminals in the telecommunications system at once.

The illustrative embodiment of the present invention comprises: forming a data frame comprising a header field, a payload field, and a framewide parity field, wherein the payload field comprises a first parity subfield; populating the framewide parity field with at least one parity bit from a first error-control coding scheme that can detect at least i bit errors in the data frame, wherein i is a positive integer; and populating the first parity subfield with at least one parity bit from a second error-control coding scheme that can correct at least j bit errors in the header field, wherein j is a positive integer.

### BRIEF DESCRIPTION OF THE DRAWINGS

FIG. 1 depicts a schematic diagram of the illustrative embodiment of the present invention.

FIG. 2 depicts a block diagram of the salient components of terminal 102-x, for x=1 through N, in accordance with the illustrative embodiment of the present invention.

FIG. 3 depicts an illustration of the legacy data frame format in accordance with the illustrative embodiment of the present invention.

FIG. 4 depicts an illustration of the format of payload field 302 in accordance with the first variation of the illustrative embodiment of the present invention.

FIG. 5 depicts an illustration of the format of payload field 302 in accordance with the second variation of the illustrative embodiment of the present invention.

FIG. 6 depicts a flowchart of the tasks performed by a legacy terminal in forming and transmitting a legacy data frame on shared-bandwidth telecommunications network 101.

FIG. 7 depicts a flowchart of the tasks performed by an upgraded terminal in forming and transmitting a data frame that conforms to the second variation of the upgraded data frame format, on shared-bandwidth telecommunications network 101.

FIG. 8 depicts a flowchart of the tasks performed by a legacy terminal in receiving and decoding a data frame.

FIG. 9 depicts a flowchart of the tasks performed by an upgraded terminal in receiving and decoding both a legacy data frame and an upgraded data frame on shared-bandwidth telecommunications network 101.

### DETAILED DESCRIPTION

FIG. 1 depicts a schematic diagram of the illustrative embodiment of the present invention, telecommunications system 100, which transmits signals between terminals 102-1 through 102-N, wherein N is a positive integer, over shared-bandwidth telecommunications network 101.

In accordance with the illustrative embodiment, telecommunications system 100 is a packet-switched network, in contrast to a circuit-switched network, as is well known to those skilled in the art. In other words, a macro data structure (e.g., a text file, a portion of a voice conversation, etc.) of indefinite size is not necessarily transmitted across shared-bandwidth telecommunications network 101 intact, but rather might be transmitted in small pieces.

Each of these small pieces is encapsulated into a data structure called a “data frame,” and each data frame traverses shared-bandwidth telecommunications network 101 independently of the other data frames. The intended receiver of the macro data structure collects all of the data frames as they are received, recovers the small pieces of data from each, and reassembles them into the macro data structure. This process is described in more detail below.

Shared-bandwidth telecommunications network 101 can be a wireless or wireline or hybrid wireless and wireline network. A salient characteristic of shared-bandwidth telecommunications network 101 is that every data frame transmitted on shared-bandwidth telecommunications network 101 by any terminal is received or “seen” by every terminal on shared-bandwidth telecommunications network 101, regardless of whether the data frame was intended for it or not. In other words, each of terminals 102-1 through 102-N shared-bandwidth telecommunications network 101 is effectively a broadcast medium.

Because each terminal receives both data frames intended for it and data frames not intended for it, the illustrative embodiment incorporates a mechanism that enables each terminal to distinguish between the two. This mechanism is described in detail below. It will be clear to those skilled in the art how to make and use shared-bandwidth telecommunications network 101. It will also be clear to those skilled in the art that the shared-bandwidth telecommunications network depicted in FIG. 1 is illustrative only and that other types of telecommunications networks are within the scope of the present invention.

Terminals 102-1 through 102-N receive or generate the macro data structure and prepare it for transmission over shared-bandwidth telecommunications network 101. The macro data structure can represent, for example, telemetry, text, audio, video, etc. Alternatively, one or more of terminals 102-1 through 102-N (e.g., terminal 102-2, etc.) can function as gateways between shared-bandwidth telecommunications network 101 and other telecommunications networks. In functioning as a gateway, a terminal receives the macro data structure from another telecommunications network.

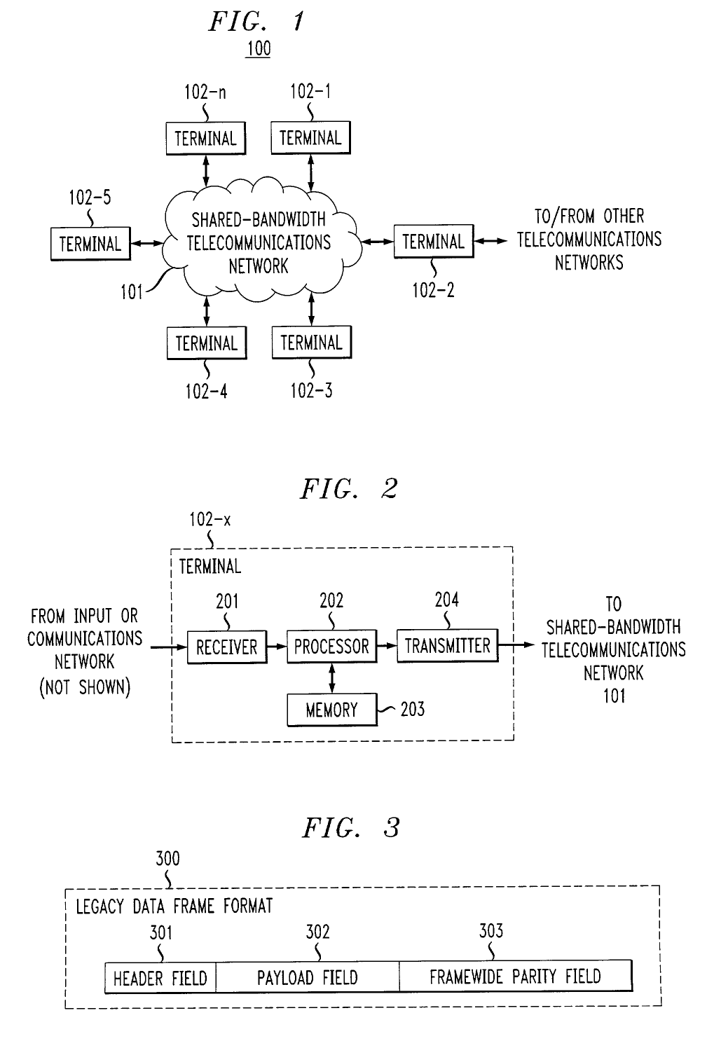

FIG. 2 depicts a block diagram of the salient components of terminal 102-x, for x=1 through N, in accordance with the illustrative embodiment of the present invention. Receiver 201 comprises the wireless or wireline or hybrid wireless and wireline interface circuitry that enables terminal 102-x to receive data frames from shared-bandwidth telecommunications network 101. When receiver 201 receives a data frame from shared-bandwidth telecommunications network 101, it passes the data frame to processor 202 for processing. It will be clear to those skilled in the art how to make and use receiver 201.

Processor 202 is a general-purpose or special-purpose processor that is capable of performing the functionality described below and with respect to FIGS. 3 through 9. In particular, processor 202 is capable of storing data into memory 203, retrieving data from memory 203, and of executing programs stored in memory 203. It will be clear to those skilled in the art how to make and use processor 202 and memory 203.

Transmitter 204 comprises the wireless or wireline or hybrid wireless and wireline interface circuitry that enables terminal 102-x to transmit data frames onto shared-bandwidth telecommunications network 101. It will be clear to those skilled in the art how to make and use transmitter 204.

In accordance with the illustrative embodiment of the present invention, not all of terminals 102-1 through 102-N are of identical capability. Situations involving terminals with heterogeneous capabilities can occur, for example, where modern terminals are added to a telecommunication system that comprises only legacy terminals. Additionally, the situation can result where some, but not all, of the terminals in a telecommunications system are upgraded with additional capabilities. Whatever the reason, it will be clear to those skilled in the art why telecommunications systems exist that comprise terminals with heterogeneous capabilities.

In accordance with the illustrative embodiment of the present invention, some of terminals 102-1 through 102-N are capable of detecting, but not correcting, at least one bit error in a received data frame (regardless of whether the data frame comprises sufficient redundancy to make error correction at least theoretically possible). For the purposes of this specification, these terminals are hereinafter called “legacy terminals.” In contrast, others of terminals 102-1 through 102-N are capable of detecting and correcting at least one bit error in a received data frame (provided that the data frame comprises sufficient redundancy to make error correction possible). For the purposes of this specification, these terminals are hereinafter called “upgraded terminals.” In accordance with the illustrative embodiment of the present invention, legacy terminals and upgraded terminals are capable of communicating with each other because the upgraded terminals create and transmit data frames that conforms to a data frame format that is legacy compatible with the data frame format that is created and transmitted by the legacy terminals. For the purposes of this specification, the format of a data frame that is created and transmitted by legacy terminals is hereinafter called the “legacy data frame format.”

FIG. 3 depicts an illustration of the legacy data frame format in accordance with the illustrative embodiment of the present invention. The legacy data frame format is of variable length, up to some maximum number of bits, and comprises three salient fields: header field 301, payload field 302, and parity field 303. It will be clear to those skilled in the art how to delimit and demarcate these fields within a single data frame. Furthermore, it will be clear to those skilled in the art that the order of the fields depicted in FIGS. 3 through 5 is illustrative only and that other orders of the fields are within the scope of the present invention.

Header field 301 comprises subfields that signify:

1. the address or other identifying indicium of the terminal to which the data frame is intended, and

2. a serial number or other sequential indicium of the particular data frame with respect to the other data frames associated with the same macro data structure, and

3. the perishability of the data frame.

It will be clear to those skilled in the art how to make and use header field 301. It will also be clear to those skilled in the art that header field 301 can comprise other subfields.

In accordance with the legacy data frame format, payload field 302 carries the payload data, which is all or a portion of the macro data structure.

Parity field 303 comprises at least one parity bit from a first error-control coding scheme that can detect, but not correct, at least i bit errors in the data frame (i.e., header field 301, payload field 302, and parity field 303) wherein i is a positive integer. For the purposes of this specification, an “error-control coding scheme” is defined as a system for enabling the detection or correction of one or more corrupt bits in a string of bits. As is well-known to those skilled in the art, the bits in parity field 303 represent redundancy that enable the detection of one or more corrupt bits in the data frame. It will be clear to those skilled in the art how to choose an appropriate error-control coding scheme to enable the detection of at least i bit errors in the data frame.

As stated above, legacy terminals and upgraded terminals are capable of communicating with each other because the upgraded terminals create and transmit data frames that conform to a format that is legacy compatible with the format that is created and transmitted by the legacy terminals. For the purposes of this specification, the format of a data frame that is created and transmitted by upgraded terminals is hereinafter called the “upgraded data frame format.”

The upgraded data frame format is an extension of the legacy data frame format. In other words, the upgraded data frame format comprises all of the fields, with all of their concomitant meanings, as does the legacy data frame format. Furthermore, in accordance with the upgraded data frame format, header field 301 and parity field 303 are populated in exactly the same manner as they are in accordance with the legacy data frame format. To manifest the extension of the legacy data frame format, however, in accordance with the upgraded data frame format, payload field 302 comprises at least one parity subfield.

There are two variations of the upgraded data frame format in accordance with the illustrative embodiment. In accordance with the first variation, payload field 302 comprises one parity subfield, and in accordance with the second variation, payload field 302 comprises two distinct parity subfields.

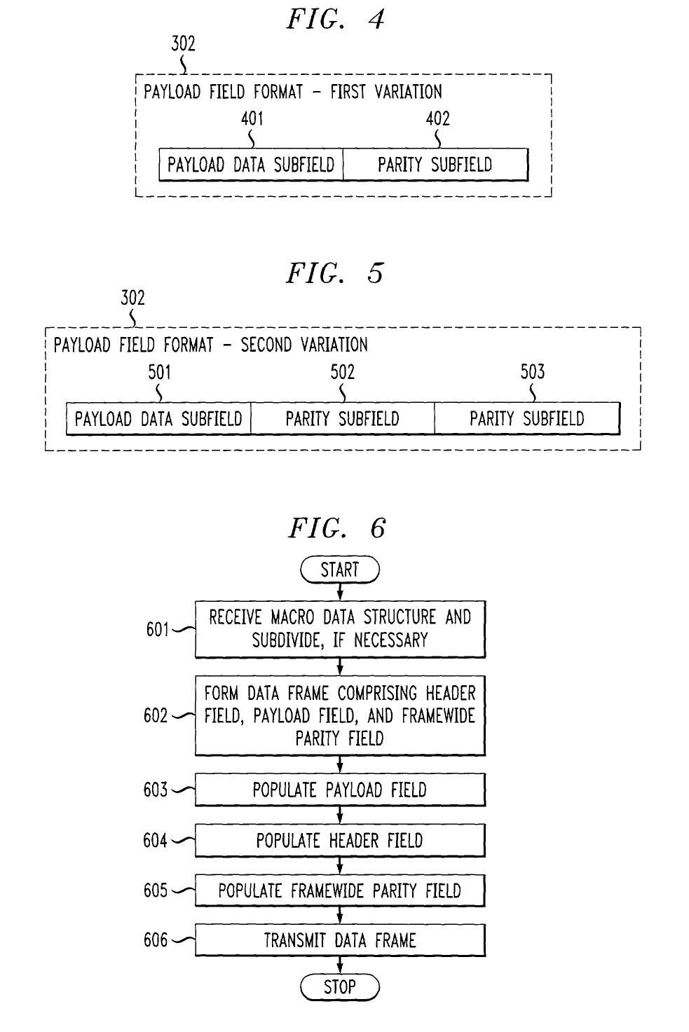

FIG. 4 depicts an illustration of the format of payload field 302 that conforms to the first variation of the illustrative embodiment of the present invention. Payload field 302 comprises:

payload data subfield 401 and parity field 402. It is essential to understand that in accordance with the illustrative embodiment, parity field 402 is a subfield of payload field 302 and not a peer of header field 301 or payload field 302 or parity field 303. The distinction is important because it is what enables the first variation of the upgraded data frame format to be legacy compatible with the legacy data frame format.

In accordance with the first variation of the illustrative embodiment of the present invention, parity field 402 comprises at least one parity bit from a second error-control coding scheme that can detect and correct at least j bit errors in:

i. all of header field 301, or

ii. a portion of header field 301, or

iii. all of payload data subfield 401, or

iv. a portion of payload data subfield 401, or

v. any combination of i, ii, iii, and iv.

wherein j is a positive integer. The second error-control coding scheme is a block error-control coding scheme (e.g., Hamming codes, cyclic codes, Bose-Chaudhuri-Hocquenghem codes, Reed-Solomon Codes, etc.) in contrast to a convolutional error-control coding scheme because it leaves the bits in header field 301 unaffected for transmission. This is essential to enable the upgraded data frame format to be legacy compatible and discernible by legacy terminals. The second error-control coding scheme is at least as strong as the first error-control coding scheme. In other words, j>i.

It will be clear to those skilled in the art how to delimit and demarcate payload data 401 and parity field 401 within payload field 302 in a manner that is legacy compatible with the legacy data frame format.

FIG. 5 depicts an illustration of the format of payload field 302 in accordance with the second variation of the illustrative embodiment of the present invention. Payload field 302 comprises:

payload data subfield 501, parity field 502, and parity field 503. It is essential to understand that in accordance with the illustrative embodiment, parity field 502 and parity field 503 are subfields of payload field 302 and not peers of either header field 301 or payload field 302 or parity field 303. The distinction is important because it is what enables the second variation of the upgraded data frame format to be legacy compatible with the legacy data frame format.

In accordance with the second variation of the illustrative embodiment, parity field 502 comprises at least one parity bit from a second error-control coding scheme that can detect and correct at least j bit errors in all of header field 30l or in any portion of header field 301, wherein j is a positive integer.

In accordance with the second variation of the illustrative embodiment, parity field 503 comprises at least one parity bit from a third error-control coding scheme that can detect and correct at least k bit errors in all of payload field 302 or in any portion of payload field 302 (e.g., payload data subfield 501, etc.), wherein k is a positive integer.

Both the second and third error-control coding schemes are block error-control coding schemes.

It is well known to those skilled in the art that there are applications (e.g., voice, video, etc.) where the information in payload data subfield 501 is inherently less sensitive to bit errors than is the information in header 301. In those applications, the second error-control coding scheme should be stronger than the third error-control coding scheme. In other words, j≧k. Furthermore, both the second error-control coding scheme and the third error-control coding scheme should be at least as strong as the first error-control coding scheme. In other words, j≧i and k≧i. When these three relations are algebraically combined, the relative strength of the three error-control coding schemes in accordance with the second variation is: j≧k≧i.

FIG. 6 depicts a flowchart of the tasks performed by a legacy terminal in forming and transmitting a data frame that conforms to the legacy data frame format, on shared-bandwidth telecommunications network 101. It will be clear to those skilled in the art which of the tasks depicted in FIG. 6 can be performed simultaneously or in a different order than that depicted in FIG. 6.

At task 601, the legacy terminal receives or generates a macro data structure, which macro data structure might be too large to transmit in one data frame. When the macro data structure is, in fact, too large to transmit in one data frame, it is divided into a plurality of smaller pieces each of which can fit into the payload field of a single data frame that conforms to the legacy data frame format. The smaller pieces can be assigned a serial number or other sequential indicium to inform the receiving terminal how to reassemble the pieces. Depending on the protocol, the serial number or other sequential indicium can be included in either the data frame header field or the data frame payload field.

At task 602, the legacy terminal forms a legacy data frame as depicted in FIG. 3. It will be clear to those skilled in the art how to delimit and demarcate the fields in the data frame.

At task 603, the legacy terminal populates payload field 302 with the entire macro data structure if it fits in payload field 302 or as much of it as fits into payload field 302. It will be clear to those skilled in the art how to determine how much of the macro data structure will fit into payload field 302.

At task 604, the legacy terminal populates header field 301.

At task 605, the legacy terminal populates parity field 303 with at least one parity bit from a first error-control coding scheme that can detect at least i bit errors in the data frame. It will be clear to those skilled in the art how to populate parity field 303. Furthermore, it will be clear to those skilled in the art that parity field 303 cannot be populated until both header field 301 and payload filed 302 have been populated.

At task 606, the legacy terminal transmits the fully populated legacy data frame onto shared-bandwidth telecommunications network 101.

It will be clear to those skilled in the art how to perform each of tasks 601 through 606.

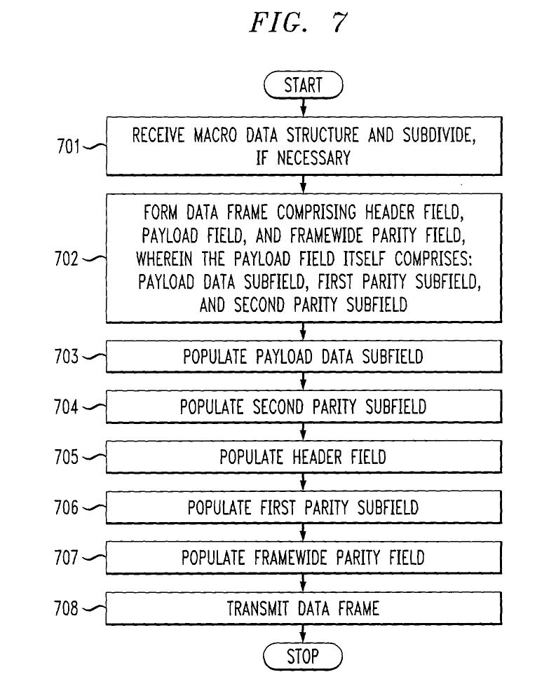

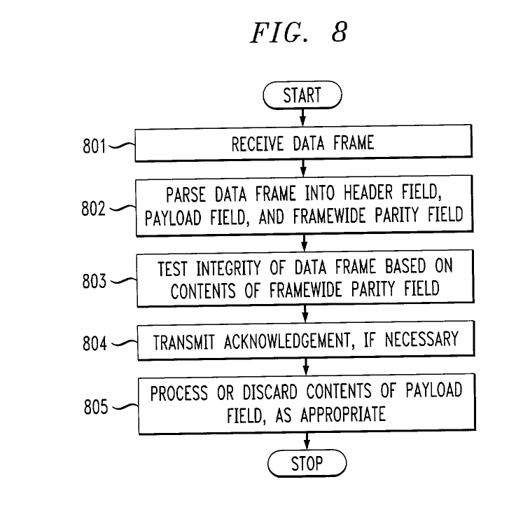

FIG. 7 depicts a flowchart of the tasks performed by an upgraded terminal in forming and transmitting a data frame that conforms to the second variation of the upgraded data frame format, on shared-bandwidth telecommunications network 101. It will be clear to those skilled in the art which of the tasks depicted in FIG. 7 can be performed simultaneously or in a different order than that depicted in FIG. 7.

At task 701, the upgraded terminal receives or generates a macro data structure, which macro data structure might be too large to transmit in one data frame. When the macro data structure is, in fact, too large to transmit in one data frame, it is divided into a plurality of smaller pieces each of which can fit into a single data frame. The smaller pieces can be assigned a serial number or other sequential indicium to inform the receiving terminal how to reassemble the pieces. Depending on the protocol, the serial number or other sequential indicium can be included in either the data frame header field or the data frame payload field.

At task 702, the upgraded terminal forms an upgraded data frame as depicted in FIGS. 3 and 5. It will be clear to those skilled in the art how to delimit and demarcate the fields in the data frame. Furthermore, it will be clear to those skilled in the art how to create an indication in payload 302 that signals to an upgraded terminal that the data frame utilizes the upgraded data frame format but does not suggest to a legacy terminal that the data frame utilizes anything but the legacy data frame format.

At task 703, the upgraded terminal populates payload data subfield 501 with the entire macro data structure if it fits in payload data subfield 501 or as much of it as fits into payload data subfield 501. It will be clear to those skilled in the art that the presence of parity field 502 and parity field 503 in payload field 302 might diminish the quantity of data that fits into payload 501.

At task 704, the upgraded terminal populates parity field 503 with at least one parity bit from a third error-control coding scheme that can detect and correct at least k bit errors in payload data subfield 501.

At task 705, the upgraded terminal populates header field 301.

At task 706, the upgraded terminal populates parity field 502 with at least one parity bit from a second error-control coding scheme that can detect and correct at least j bit errors in all of header field 301.

At task 707, the upgraded terminal populates parity field 303 with at least one parity bit from a first error-control coding scheme that can detect at least i bit errors in the data frame.

At task 708, the upgraded terminal transmits the fully populated legacy data frame onto shared-bandwidth telecommunications network 101.

It will be clear to those skilled in the art how to perform each of tasks 701 through 708.

FIG. 8 depicts a flowchart of the tasks performed by a legacy terminal in receiving and decoding a data frame, whether the data frame conforms to the legacy data frame format or the upgraded data frame format. It will be clear to those skilled in the art which of the tasks depicted in FIG. 8 can be performed simultaneously or in a different order than that depicted in FIG. 8.

At task 801, the legacy terminal receives a data frame from shared-bandwidth telecommunications network 101.

At task 802, the legacy terminal parses the data frame into its constituent header field, payload field, and parity field. When the data frame conforms to the upgraded data frame format, the legacy terminal is incapable of detecting that fact and ignores the presence of the second and second parity subfields in the payload field.

At task 803, the legacy terminal uses the parity bits in the parity field and the first error-control coding scheme to test the integrity of the bits in the data frame to determine if there are any bit errors in the data frame.

At task 804, the legacy terminal transmits an acknowledgment, in well-known fashion, if the data frame is intended for the legacy terminal and the parity bits in the parity field suggest that the data frame has been received without bit errors.

At task 805, the legacy terminal processes the data frame, in well-known fashion, if the data frame is intended for the legacy terminal and the parity bits in the parity field suggest that the data frame has been received without any bit errors.

It will be clear to those skilled in the art how to perform tasks 801 through 805.

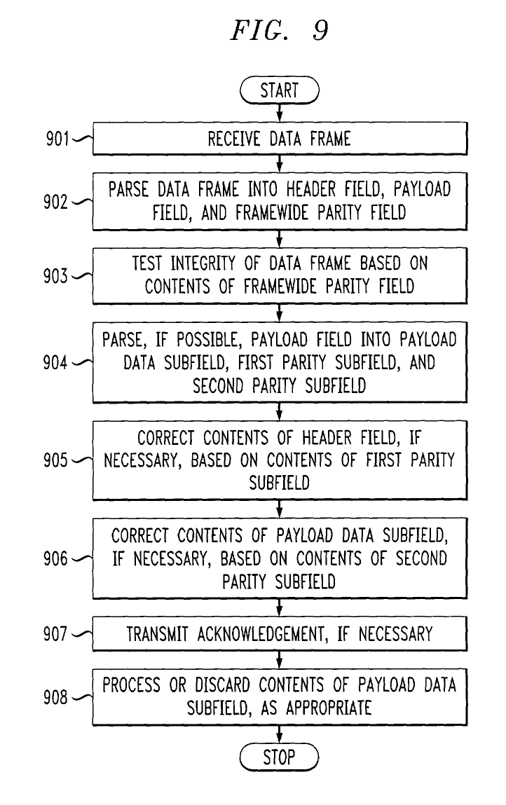

FIG. 9 depicts a flowchart of the tasks performed by an upgraded terminal in receiving and decoding both a legacy data frame and an upgraded data frame on shared-bandwidth telecommunications network 101. It will be clear to those skilled in the art which of the tasks depicted in FIG. 9 can be performed simultaneously or in a different order than that depicted in FIG. 9.

At task 901, the upgraded terminal receives a data frame from shared-bandwidth telecommunications network 101.

At task 902, the upgraded terminal parses the data frame into its constituent header field, payload field, and parity field.

At task 903, the upgraded terminal uses the parity bits in the parity field and the first error-control coding scheme to test the integrity of the bits in the data frame to determine if there are any bit errors in the data frame.

At task 904, the upgraded terminal attempts to parse the payload field into the payload data subfield, the first parity subfield and the second parity subfield. If the payload field reveals a data structure comprising the payload data subfield, the first parity subfield and the second parity subfield, then the upgraded terminal knows that the data frame conforms to the upgraded data frame format. If the payload field does not reveal a data structure comprising the expected subfields, then the upgraded terminal knows that the data frame conforms to the legacy data frame format and tasks 905 and 906 are omitted.

At task 905, the upgraded terminal uses the parity bits in the first parity subfield to test the integrity of the bits in the header field, and, if possible, to correct any bit errors in the header field.

At task 906, the upgraded terminal uses the parity bits in the second parity subfield to test the integrity of the bits in the payload data subfield, and, if possible, to correct any bit errors in the payload data subfield.

At task 907, the upgraded terminal transmits an acknowledgment, in well-known fashion, if the data frame is intended for the upgraded terminal and the parity bits in the framewide parity field suggest that the data frame has been received without bit errors.

At task 908, the upgraded terminal processes the data frame, in well-known fashion, if the data frame is intended for the upgraded terminal and the parity bits in the parity field suggest that the data frame has been received without any bit errors.

It will be clear to those skilled in the art how to perform tasks 901 through 908.

It is to be understood that the above-described embodiments are merely illustrative of the present invention and that many variations of the above-described embodiments can be devised by those skilled in the art without departing from the scope of the invention. It is therefore intended that such variations be included within the scope of the following claims and their equivalents.

What is claimed is:

1. A method comprising:
forming a data frame comprising a header field, a payload field, and a framewide parity field, wherein said payload field comprises a first parity subfield;
populating said framewide parity field with at least one parity bit from a first error-control coding scheme that can detect at least i bit errors in said data frame, wherein i is a positive integer; and
populating said first parity subfield with at least one parity bit from a second error-control coding scheme that can correct at least j bit errors in said header field, wherein j is a positive integer.

2. The method of claim 1 wherein j≧i.

3. The method of claim 1 wherein said at least one parity bit from said second error-control coding scheme can correct at least j bit errors in said payload field.

4. The method of claim 1 wherein said second error-control coding scheme is a block error-control coding scheme.

5. The method of claim 1 further comprising populating a second parity subfield with at least one parity bit from a third error-control coding scheme that can correct at least k bit errors in said payload field, wherein k is a positive integer.

6. The method of claim 5 wherein k≧i.

7. The method of claim 5 wherein j≧k.

8. The method of claim 5 wherein j≧k≧i.

9. An apparatus comprising:
a processor for forming a data frame comprising a header field, a payload field, and a framewide parity field, wherein said payload field comprises a first parity subfield, for populating said framewide parity field with at least one parity bit from a first error-control coding scheme that can detect at least i bit errors in said data frame, wherein i is a positive integer, and for populating said first parity subfield with at least one parity bit from a second error-control coding scheme that can correct at least j bit errors in said header field, wherein j is a positive integer; and
a transmitter for transmitting said data frame onto a shared-bandwidth telecommunication network.

10. The apparatus of claim 9 wherein j≧i.

11. The apparatus of claim 9 wherein said at least one parity bit from a second error-control coding scheme can correct at least j bit errors in said payload field.

12. The apparatus of claim 9 wherein said second error-control coding scheme is a block error-control coding scheme.

13. The apparatus of claim 9 further comprising populating a second parity subfield with at least one parity bit from a third error-control coding scheme that can correct at least k bit errors in said payload field, wherein k is a positive integer.

14. The apparatus of claim 13 wherein k≧i.

15. The apparatus of claim 13 wherein j≧k.

16. The apparatus of claim 13 wherein j≧k≧i.

17. A method comprising:
forming a data frame comprising a header field, a payload field, and a framewide parity field, wherein said payload field comprises: a payload data subfield, a first parity subfield, and a second parity subfield;
populating said framewide parity field with at least one parity bit from a first error-control coding scheme that can detect at least i bit errors in said data frame, wherein i is a positive integer;
populating said first parity subfield with at least one parity bit from a second error-control coding scheme that can correct at least j bit errors in said data frame, wherein j is a positive integer; and
populating said second parity subfield with at least one parity bit from a third error-control coding scheme that can correct at least k bit errors in said payload data subfield, wherein k is a positive integer.

18. The method of claim 17 wherein j≧i.

19. The method of claim 17 wherein j≧k.

20. The method of claim 17 wherein j≧k≧i.

21. The method of claim 17 wherein said second error-control coding scheme is a block error-control coding scheme, and wherein said third error-control coding scheme is a block error-control coding scheme.
